(19) United States
(12) Patent Application Publication
(10) Pub. No.: US 2002/0132413 A1
(43) Pub. Date: Sep. 19, 2002

(54) Method of fabricating a MOS transistor

(76) Inventors: Ting-Chang Chang, Hsin-Chu City (TW); Huang-Chung Cheng, Hsin-Chu City (TW); Cheng-Jer Yang, Ping-Chen City (TW)

Correspondence Address: NAIPO (NORTH AMERICA INTERNATIONAL PATENT OFFICE), P.O. BOX 506, MERRIFIELD, VA, 22116, US

(21) Appl. No.: 09/803,887

(22) Filed: Mar. 13, 2001

(51) Int. Cl. H01L 21/8238

(52) U.S. Cl. 438/211

(57) ABSTRACT

The present invention provides a method for fabricating a metal-oxide-semiconductor (MOS) transistor on the surface of a semiconductor wafer. The present method first forms a stacked structure comprising a dielectric layer, a doped polysilicon layer, and a sacrificial layer, respectively, in the active area of the surface of the semiconductor wafer. Next, two lightly doped drains are then formed adjacent to the stacked structure. A spacer is then formed around the stacked structure, followed by an ion implantation process to form a source and drain of the MOS transistor. Then, the sacrificial layer is removed to form a trough with the spacer and the doped polysilicon layer. A self-aligned silicide (salicide) process is then performed to form a silicide layer on the surface of the source, drain, and doped polysilicon layer. Finally, a tungsten (W) layer is formed on the surface of each silicide layer and filling the trough to complete the fabrication of the MOS transistor according to the present invention.

### FIELD OF THE INVENTION

The present invention relates to a method of fabricating a metal-oxide-semiconductor (MOS) transistor on a semiconductor wafer, and more particularly, to a method of fabricating a MOS transistor for reducing the contact resistance of a gate, source and drain.

### DESCRIPTION OF THE PRIOR ART

A MOS transistor, the most important electrical device in present semiconductor products, is primarily used as a switch in electrical circuits. With the increase in device density of integrated circuits, device size has become smaller and smaller. When the device size is reduced to less than 0.2 μm, the contact resistance of a gate, source and drain greatly increases to affect the operation of the MOS transistor.

Please refer to FIG. 1 to FIG. 9. FIG. 1 to FIG. 9 are the schematic diagrams of a method of fabricating a MOS transistor and a metal connection according to the prior art. As shown in FIG. 1, a semiconductor wafer 10 comprises a silicon substrate 12, an active area 14 set on the surface of the silicon substrate 12, and field oxides (FOX) 16 functioning as a insulator to isolate and surround each active area 14. In the prior art, the silicon of the active area 14 on the surface of the silicon substrate 12 is oxidized to become silicon oxide that functions as a dielectric layer 18. Then, a doped polysilicon layer 20 is deposited on the surface of the semiconductor wafer 10, and covering the surface of both the dielectric layer 18 and the field oxides 16.

As shown in FIG. 2, a photoresist layer 22 is then formed on the surface of the doped polysilicon layer 20. A first photo-etching process (PEP) is used to define a gate 24 structure in the dielectric layer 18 and doped polysilicon layer 20. As shown in FIG. 3, after removing the photoresist layer 22, the gate 24 is used as a mask to perform a low-concentration ion implantation process 26 on the semiconductor wafer 10 to form lightly doped drains 28.

As shown in FIG. 4, a silicon nitride layer 30 is completely deposited on the surface of the semiconductor wafer 10 to cover the surface of the gate 24. Then, an anisotropic etching process is performed to form a spacer 32 on either side of the gate 24. As shown in FIG. 5, the spacer 32 and the gate 24 functions as masks to perform a high concentration and deeper depth second ion implantation process 34 to form a source 36 and a drain 38, and thereby completing the fabrication of the MOS transistor.

Then, in order to form Ohmic contact between the subsequent conductor and silicon and reduce the interface resistance, a MOS metallization process is usually performed to form a silicide between the conductor and the silicon. Firstly, cobalt (Co), titanium (Ti), nickel (Ni) or tungsten (W) metal layer (not shown) is deposited on the surface of the semiconductor wafer 10. A thermal process is then performed to allow reaction of the metal layer with the silicon on the source and drain and the polysilicon on the gate, to thereby form a silicide 40, as shown in FIG. 6. Then, a wet etching process is used to remove the unreacted metal layer.

As shown in FIG. 7, a dielectric layer 42 composed of borophosphosilicate glass (BSPG) and phosphosilicate glass (PSG) is deposited, followed by heating of the BSPG/PSG to form a more planarized surface. Finally, a second PEP is performed to form at least 3 contact holes 44, 46, 48 in the dielectric layer 42 to connect gate 24, source 36 and drain 38, respectively, as shown in FIG. 8.

Finally, as shown in FIG. 9, aluminum (Al), tungsten, copper (Co) or an aluminum-copper alloy metal layer is deposited on the dielectric layer 42 and covering each contact hole 42, 44, 46 to form metal plugs 50, 52, 54. A photoresist layer and etching process are used to define the pattern of the metal layer to complete the metallization process of the MOS transistor.

In the prior art, when the device size of the MOS transistor is less than 0.2 μm, the resistance of the gate, source and drain greatly increases. Particularly, when the MOS transistor operates in the inversion layer, higher resistance will cost part of the gate bias in the gate to thereby influence the performance of the device.

### SUMMARY OF THE INVENTION

It is therefore a primary objective of the present invention to provide an improved method of fabricating a MOS transistor with low resistance of gate, source and drain, to solve the above-mentioned problem.

In the preferred embodiment, the present method first forms a stacked structure comprising a dielectric layer, a doped polysilicon layer, and a sacrificial layer, respectively. Next, a first ion implantation process is performed to form lightly doped drains (LDD) of the MOS transistor. A spacer is then formed on the surface of the sidewalls along the stacked structure, followed by a second ion implantation process to form a source and drain of the MOS transistor. Then, the sacrificial layer is removed to form a trough with the surrounding spacer and the doped poly silicon layer. A self-aligned silicide (salicide) process is performed to form a silicide layer on the surface of the source, the drain, and the doped polysilicon layer. Finally, a tungsten (W) layer is formed on the surface of each silicide layer and filling the trough to complete the fabrication of the MOS transistor according to the present invention.

The present invention uses the silicide and selective tungsten as a metal gate, source, and drain to provide a low resistance of gate, source and drain, and simultanously, to reduce the depletion problem when polysilicon functions as a gate, thus heightening the quality of device operation.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 9 are schematic diagrams of a method of fabricating a MOS transistor according to the prior art.

FIG. 10 to FIG. 18 are schematic diagrams of a method of fabricating a MOS transistor according to the first embodiment of the present invention.

FIG. 19 is schematic diagram of the structure of a MOS transistor according to the second embodiment of the present invention.

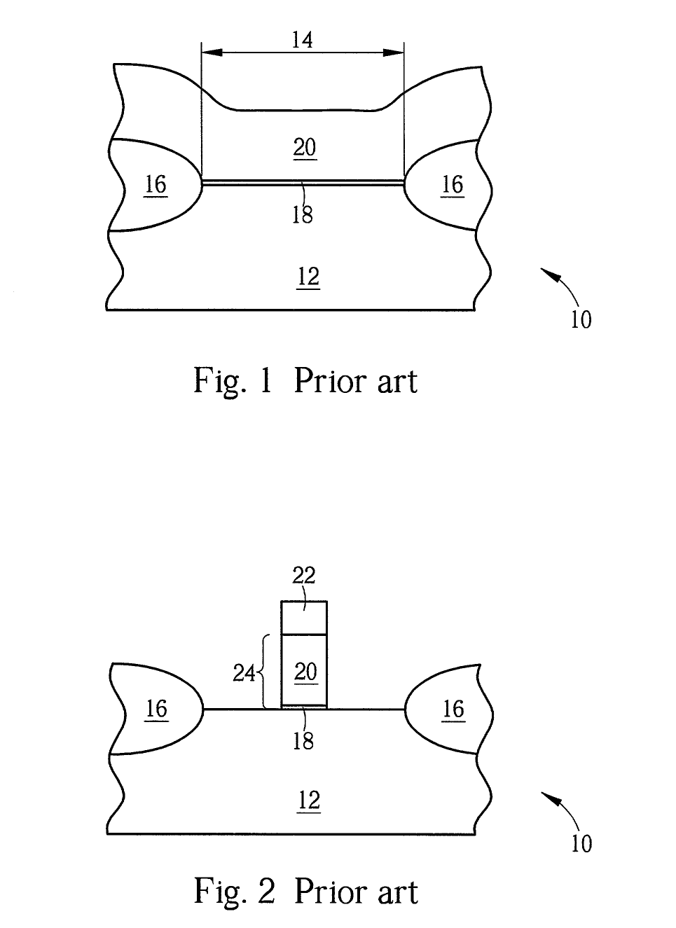

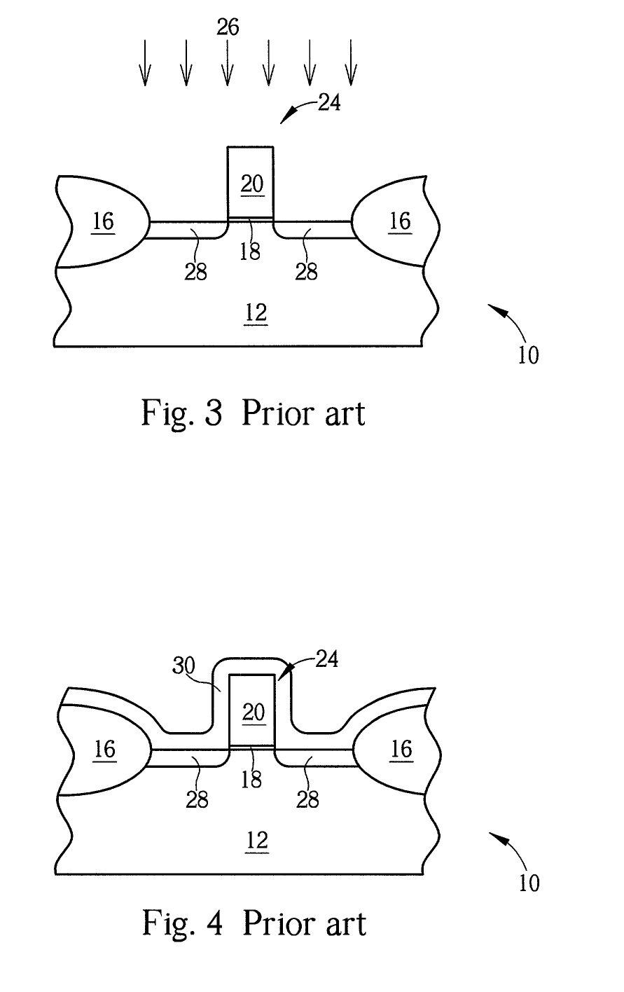

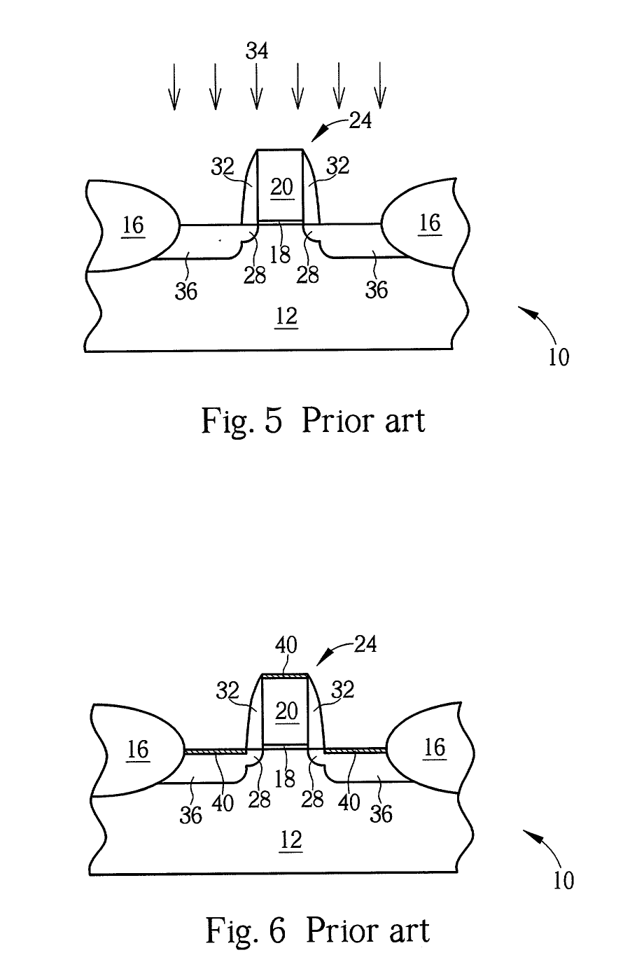

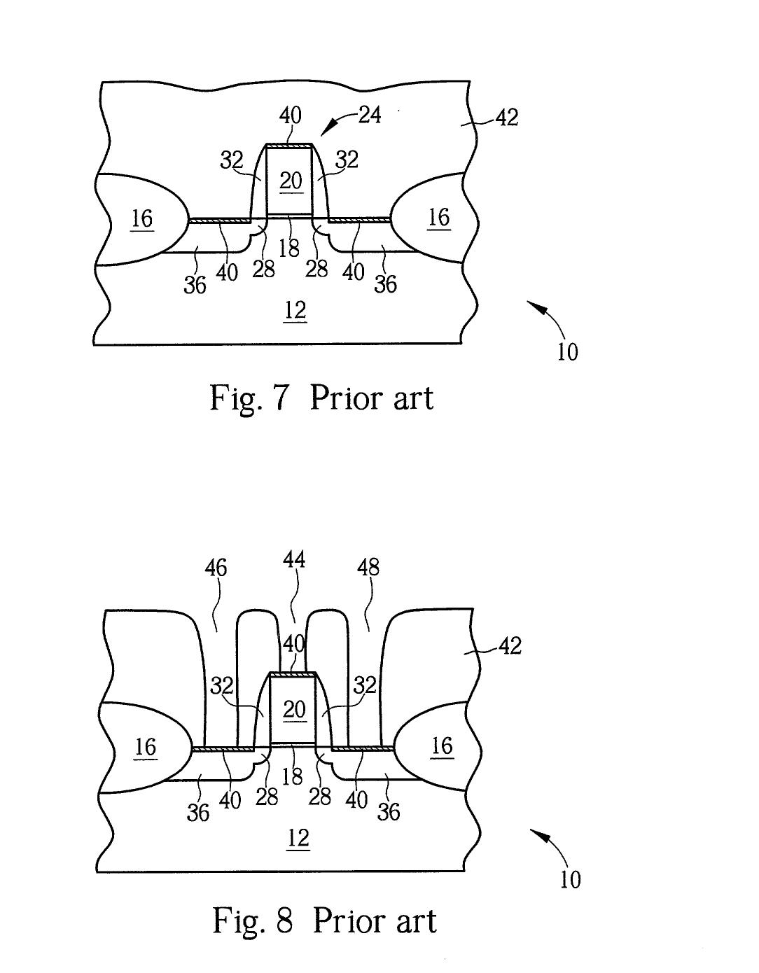

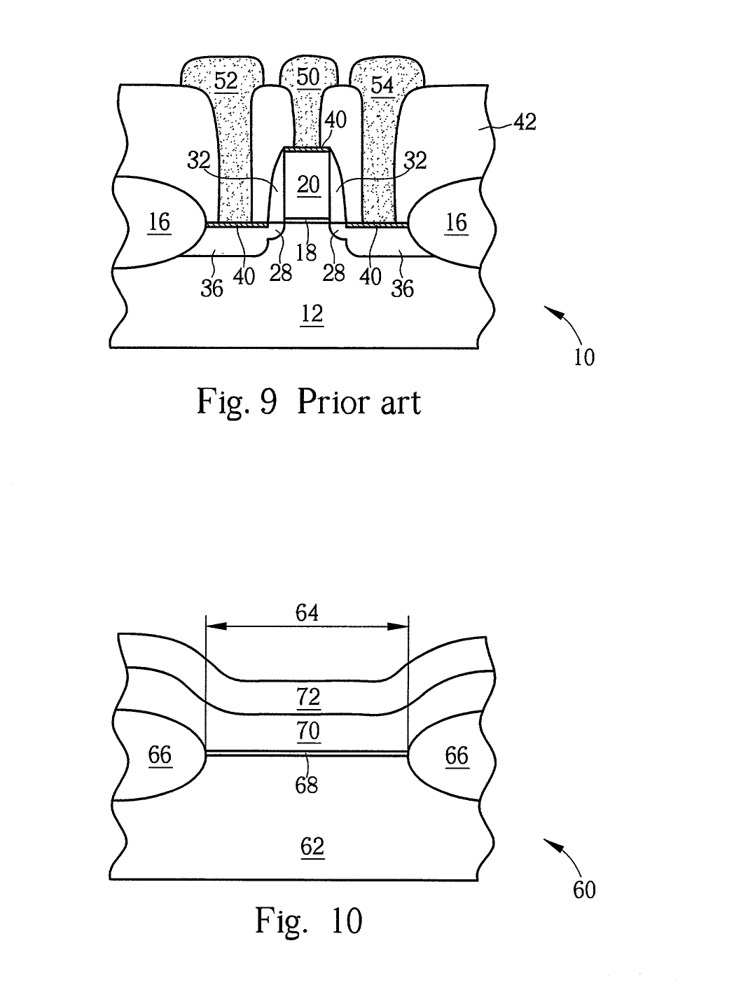

### DESCRIPTION OF THE PREFERRED EMBODIMENT

Please refer to FIG. 10 to FIG. 18. FIG. 10 to FIG. 18 are the schematic diagrams of the fabrication of a MOS transistor on a semiconductor wafer 60 according to the preferred embodiment of the present invention. As shown in FIG. 10, the semiconductor wafer 60 comprises a silicon substrate 62, an active area 64 set on the surface of the silicon substrate 62, and field oxides (FOX) 66 functioning as an insulator to isolate and surround each active area 64. Wherein, other insulating methods, such as shallow trench isolation (STI) is also applicable to the present invention.

The present invention first places the semiconductor wafer 60 in an oxidation furnace, and a dry oxidation process oxidizes the silicon of the active area 64 on the surface of the silicon substrate 62 to become silicon oxide, with a thickness of 100-200 angstroms, functioning as a dielectric layer 68. Then, a low pressure chemical vapor deposition (LPCVD) technique is used to deposit a doped polysilicon layer 70 and a sacrificial layer 72 on the surface of the semiconductor wafer 60, respectively. The sacrificial layer 72 is composed of a low resistance organic or inorganic material such as spin-on-glass (SOG) or a silicon oxide compound.

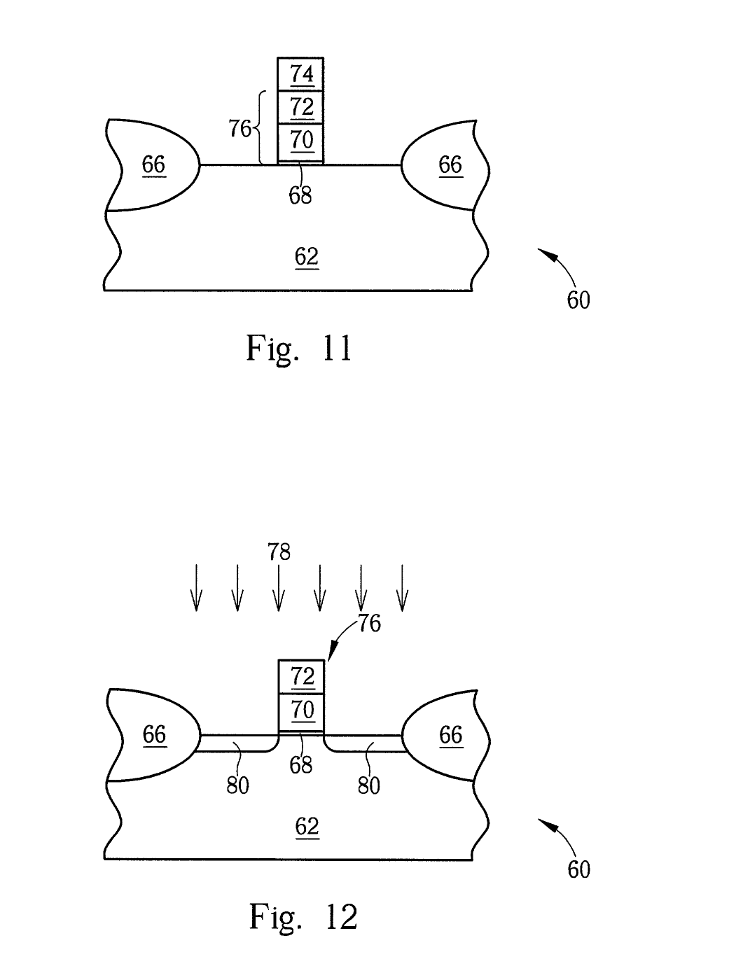

As shown in FIG. 11, a photoresist layer 74 is then formed on the surface of the sacrificial layer 72. A first photo-etching process (PEP) is then used to define a gate 76 structure in the dielectric layer 68, doped polysilicon layer 70 and sacrificial layer 72. As shown in FIG. 12, after-removing the photoresist layer 74, the gate 76 is used as a mask to perform a low-concentration ion implantation process 78 on the semiconductor wafer 60 to form lightly doped drains 80. Taking a P-type substrate as an example, the implantation number is about 10¹³/cm², primarily in functioning to prevent short channel effects.

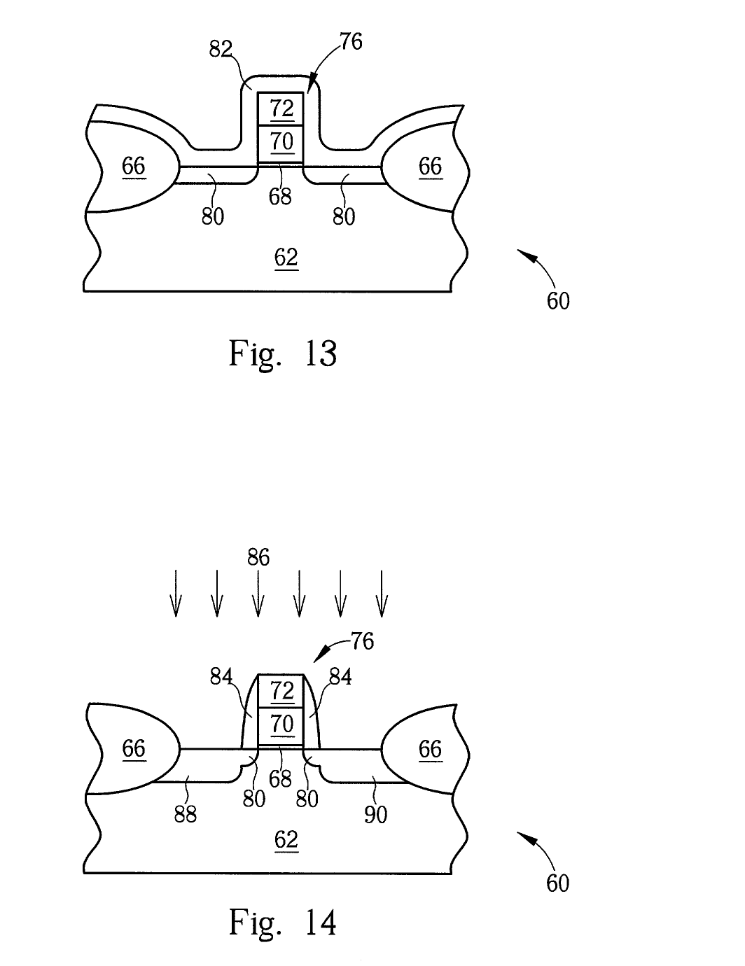

As shown in FIG. 13, a silicon nitride layer 82 is deposited on the surface of the semiconductor wafer 60 to cover the surface of the gate 76, whereby other compounds such as silicon oxide layer is also applicable to the present invention in forming a spacer in the subsequent step. Prior to the etch back process of forming the spacer, an annealing process at 900-1000° C. is performed to allow diffusion of the phosphorus atoms, and simultaneously, to recover a portion of the silicon structures damaged by the implantation process.

As shown in FIG. 14, an anisotropic etching process is then performed to remove a portion of the silicon nitride layer 82, whereby the remaining silicon nitride layer 82 on the sidewall surrounding the gate 76 forms a spacer 84. Both the spacer 84 and the gate 76 function as masks to perform a high concentration and deeper depth second ion implantation process 86 on the semiconductor wafer 60 to form a source 88 and a drain 90. The implantation concentration is about 10¹⁵/cm².

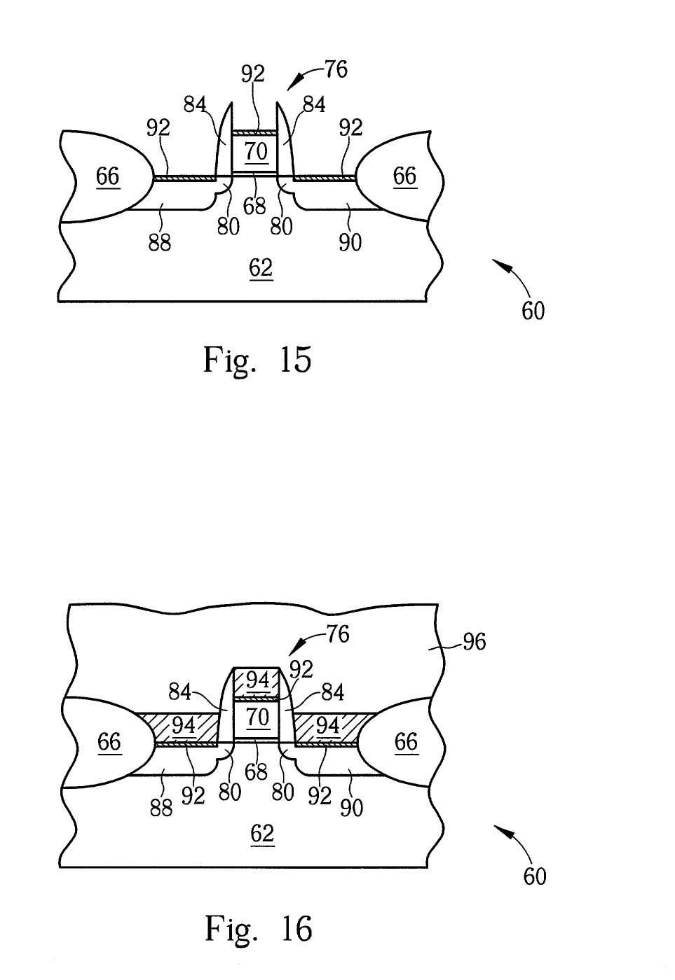

As shown in FIG. 15, the sacrificial layer 72 in the gate 76 is then removed to form a trough with the surrounding gate spacer 84 and the doped polysilicon layer 70 in the gate 76. Then, a silicide process is performed, whereby a self-aligned silicide (salicide) process in the case of a 0.5 μm semiconductor wafer process, to form silicide. Firstly, cobalt, titanium, nickel or a tungsten metal layer (not shown) with a thickness of 200-1000 angstroms is deposited on the surface of the semiconductor wafer 60 by sputtering, and covering both the surface of the gate 76 and the spacer 84. A thermal process is then performed to allow reaction between the metal layer and the silicon on the source 88 and drain 90 and the polysilicon in the gate 76, to thereby form a silicide layer 92. Then, a wet etching process is used to remove the unreacted metal layer.

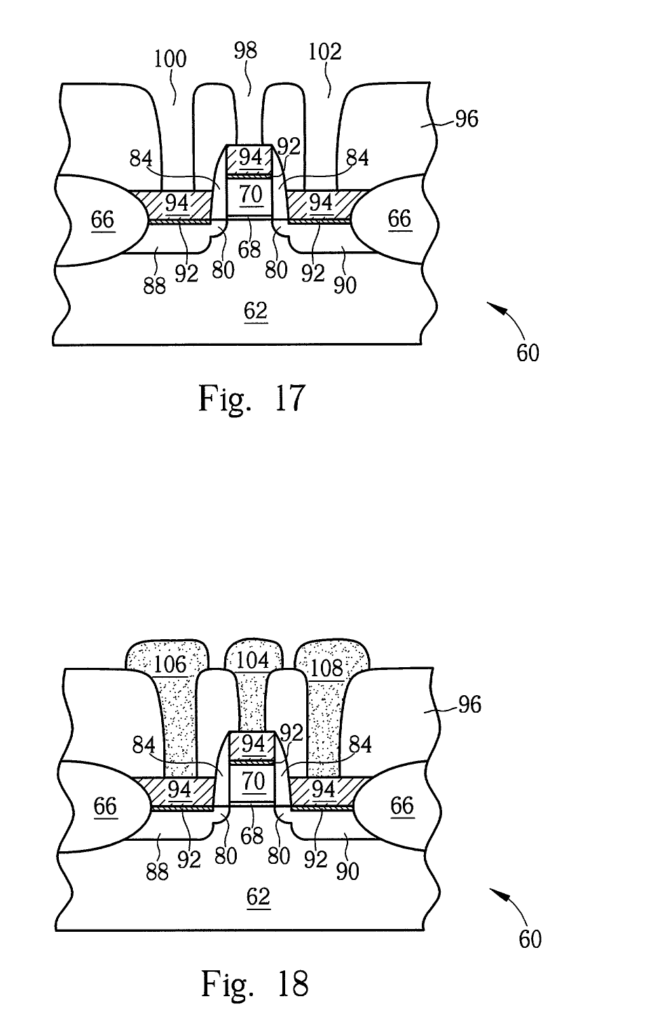

As shown in FIG. 16, a selective chemical vapor deposition is then used to form a tungsten metal layer 94 on each silicide layer above the gate 76, source 88 and drain 90 and filling the trough formed by both the spacer 84 and polysilicon layer 70 of the gate 76. Next, a chemical vapor deposition (CVD) is used to deposit borophosphosilicate glass (BSPG) or phosphosilicate glass (PSG) on the surface of the semiconductor wafer 60 to function as a dielectric layer 96. Then, a glass-flow transformation temperature of 850-950° C. is attained to allow the BSPG/PSG to have a more planarized surface. Finally, a second PEP is performed to form at least 3 contact holes 98, 100, 102 in the dielectric layer 96 to connect gate 76, source 88 and drain 90, respectively, as shown in FIG. 17.

Finally as shown in FIG. 18, aluminum (Al), tungsten, copper (Co) or an aluminum-copper alloy metal layer is deposited on the dielectric layer 96 by a sputtering or CVD process and covering each contact hole 98, 100, 102 to form metal plugs 104, 106, 108, so as to electrically connect to gate 76, source 88, drain 90. A photoresist layer and etching process is used to define the pattern of metal layer to complete the MOS and metallization process of the MOS transistor.

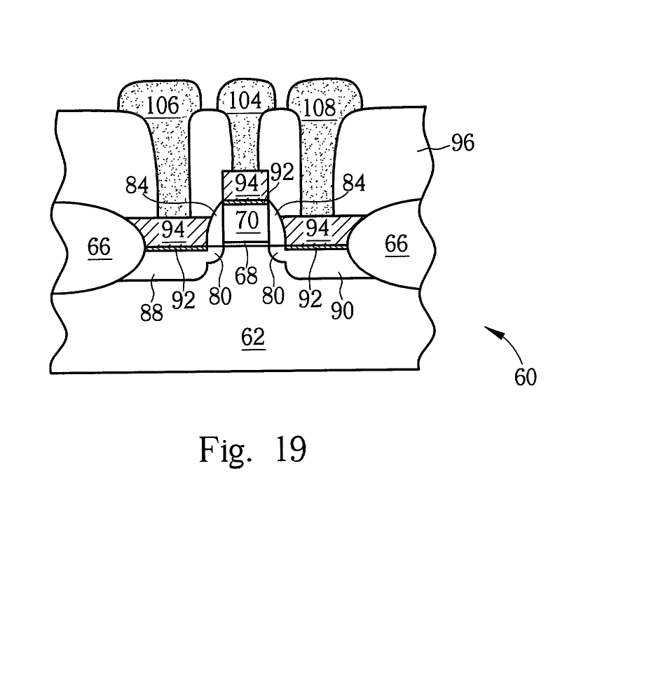

Please refer to FIG. 19. FIG. 19 is the schematic diagram of a MOS transistor structure according to the second embodiment of the present invention. The present invention omits the step of performing the etch back process of the sacrificial layer 72 in the preferred embodiment. More specifically, following the formation of the gate and the surrounding spacer, a selective chemical vapor deposition is immediately performed to form a tungsten metal layer 94 on the silicide layer 92 above the gate 76. Thus, the tungsten metal layer 94, unprotected by the spacer 84, differs with that of the preferred embodiment of FIG. 18 which is protected by the spacer 84 to control the deposition shape of the tungsten metal layer 94.

Since the present invention uses silicide and selective tungsten deposition to form Ohmic contact in the gate, source and drain so as to reduce the contact resistance of the MOS transistor, the sheet resistance between the contact plugs and gate, source or drain is thereby reduced to form a low resistance gate, source and drain of the MOS transistor.

In contrast to the prior art method for fabricating a MOS transistor, the present invention uses the selective tungsten deposition on the silicide to create a low resistance of the metal gate, source, and drain. Thus, voltage loss of the gate due to high resistance is efficiently decreased, to thereby raise the electrical performance of the MOS device.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for fabricating a metal-oxide-semiconductor (MOS) transistor on the surface of a semiconductor wafer, the semiconductor wafer comprising a silicon substrate, an active area set on the surface of the silicon substrate, and a insulator set on the surface of the silicon substrate around the active area, the method comprising:
forming a stacked structure on the surface of the active area, the stacked structure comprising a dielectric layer, a doped polysilicon layer, and a sacrificial, respectively;
performing a first ion implantation process to form lightly doped drains (LDD) of the MOS transistor adjacent to the stacked structure;
forming a spacer on the surface of the sidewalls along the stacked structure;
performing a second ion implantation process to form a source and drain of the MOS transistor;
removing the sacrificial layer to form a trough with the spacer and the doped polysilicon layer;
performing a self-aligned silicide (salicide) process to form a silicide layer on the surface of the source, drain, and doped poly silicon layer; and
forming a tungsten (W) layer on the surface of each silicide layer and filling the trough to complete the fabrication of the MOS transistor.

2. The method of claim 1 wherein the method of forming the spacer comprises:
forming a silicon nitride layer on the surface of the semiconductor wafer and covering the surface of the stacked structure; and
performing an etching back process to remove a portion of the silicon nitride layer and to form a spacer from the remaining silicon nitride layer on the sidewalls around the stacked structure.

3. The method of claim 1 wherein the salicide process comprises:
forming a metal layer on the surface of the semiconductor wafer and covering the surface of both the stacked structure and the spacer;
performing a thermal process to allow reaction of the metal layer with the surface of the source, drain, and the doped polysilicon layer to form a silicide layer; and
removing the metal layer.

4. The method of claim 3 wherein the metal layer is composed of cobalt (Co), titanium (Ti), Nickel (Ni), or tungsten (W).

5. The method of claim 1 wherein the sacrificial layer is composed of organic or inorganic material with a low dielectric constant.

6. The method of claim 1 wherein the sacrificial layer is composed of a silicon oxide compound.

7. The method of claim 1 wherein the method for forming the tungsten layer on the surface of each silicide layer is by selective chemical vapor deposition.

8. The method of claim 1 wherein the insulator is a field oxide (FOX) or shallow trench isolation (STI).

9. A method for fabricating a metal-oxide-semiconductor (MOS) transistor on the surface of a semiconductor wafer, the semiconductor wafer comprising a silicon substrate on its surface, an active area set on the surface of the silicon substrate, and an insulator set on the surface of the silicon substrate around the active area, the method comprising:
forming a gate on the surface of the active area, the gate comprising a dielectric layer and a doped poly silicon layer, respectively;
performing a first ion implantation process to form lightly doped drains (LDD) of the MOS transistor adjacent to the gate;
forming a spacer on the surface of the sidewalls along the stacked structure;
performing a second ion implantation process to form a source and drain of the MOS transistor;
performing a salicide process to form a silicide layer on the surface of the source, drain, and the doped polysilicon layer; and
performing a selective chemical vapor deposition to form a tungsten layer on the surface of each silicide layer to complete the fabrication of the MOS transistor.

10. The method of claim 9 wherein the method of forming the spacer comprises:
forming a silicon nitride layer on the surface of the semiconductor wafer and covering the surface of the gate; and
performing an etching back process to remove a portion of the silicon nitride layer and to form a spacer around the gate using the remaining silicon nitride on the sidewalls around the gate.

11. The method of claim 9 wherein the salicide process comprises:
forming a metal layer on the surface of the semiconductor wafer and covering the surface of both the gate and the spacer;
performing a thermal process to allow reaction of the metal layer with the surface of the source, drain, and the doped polysilicon layer to form a silicide layer; and
removing the metal layer.

12. The method of claim 9 wherein the metal layer is composed of cobalt (Co), titanium (Ti), Nickel (Ni), or tungsten (W).

13. The method of claim 9 wherein the insulator is a field oxide (FOX) or shallow trench isolation (STI).

14. A method for reducing the contact resistance of a MOS transistor, the MOS transistor set on the surface of a semiconductor wafer, the method comprising:
forming a silicide layer on the surface of the source, drain, and gate of the MOS transistor; and
performing a selective chemical vapor deosition to form a tungsten layer on the surface of each silicide layer;
forming a dielectric layer on the surface of the semiconductor wafer;
forming at least three contact plugs in the dielectric layer to connect with each tungsten layer on the surface of the source, drain, gate of MOS transistor, respectively;
wherein each tungsten layer and each silicide layer is used to form an Ohmic contact with the surface of the source, drain and gate, so as to reduce the contact resistance of the MOS transistor, and thereby, reducing the sheet resistance between the gate, source, and drain and each contact plug.

15. The method of claim 14 wherein the dielectric layer is composed of phosphosilicate glass (PSG) or borophosphosilicate glass (BPSG).

16. The method of claim 14 wherein the contact plugs are composed of tungsten (W), aluminum (Al), copper (Cu) or an aluminum-copper alloy.
